(19) United States
(12) Patent Application Publication
(10) Pub. No.: US 2025/0260392 A1
(43) Pub. Date: Aug. 14, 2025

(54) Polyphase Filter Banks with Rational Decimation / Interpolation Factor

(71) Applicant: RAMON SPACE LTD., Yokneam Illit (IL)

(72) Inventors: Hai Morgenstern, Tel Aviv-Yafo (IL); Eviatar Ohayon, Shoham (IL)

(21) Appl. No.: 19/050,142

(22) Filed: Feb. 11, 2025

Related U.S. Application Data
(60) Provisional application No. 63/553,180, filed on Feb. 14, 2024.

(51) Int. Cl. H03H 17/02; G06F 7/52

(52) U.S. Cl. CPC H03H 17/0273; G06F 7/52; H03H 17/0201

(57) ABSTRACT

An Analysis Polyphase Filter (APPF) for shifting a selected passband of an input signal to a passband signal, having a Q=M·B/A decimation factor, B and A being co-primes, the APPF comprising M·B Paths. Each path includes (i) M·B/A multiplication Sub-paths, and (ii) a Sub-path Fusion Circuit, which is configured to generate fused multiplication products responsively to a sum of the multiplication n products generated by each of the multiplication sub-paths.

### FIELD OF THE INVENTION

The present invention relates generally to signal processing, and particularly to digital filters.

### CROSS REFERENCE TO RELATED APPLICATIONS

This application claims the benefit of U.S. Provisional Patent Application, 63/553,180, filed Feb. 14, 2024, whose disclosure is incorporated herein by reference.

### BACKGROUND OF THE INVENTION

In modern communication systems, efficient frequency division and signal separation are essential for processing multiple channels simultaneously. One of the most critical tasks in such systems is the ability to divide a wideband signal into its constituent narrowband channels, a process known as channelization. This is crucial in applications such as software-defined radios (SDRs), cognitive radio, satellite communications, and other wireless systems, where multiple signals must be analyzed or transmitted simultaneously over the same frequency spectrum.

A key technique for performing channelization efficiently is the use of polyphase filters, which allow efficient implementation of the channelization process with reduced computational and complexity lower power consumption.

Background on polyphase filters can be found, for example, in “Multirate Signal Processing for Communication Systems”, by F. J. Harris (Upper Saddle River, NJ, USA: Prentice-Hall, 2004). Chapter 6 therein (pp. 139-165) presents resampling low-pass and band-pass Finite Impulse Response (FIR) filters for which the noble identity has been applied to interchange the operations of resampling and filtering, and examines up-sampling, down-sampling, and cascade up-down sampling filters.

Additional background can be found in U.S. Pat. No. 10,050,607, which discloses a polyphase decimation FIR filter apparatus including a modulo integrator circuit configured to integrate input samples and to provide integrated input samples; and a polyphase FIR filter circuit configured to process the integrated input samples, the polyphase FIR filter circuit including a plurality of multiplier accumulator circuits, each configured to accumulate products of coefficients and respective integrated signal samples, to form outputs corresponding to different channels.

### SUMMARY OF THE INVENTION

An embodiment of the present invention that is described herein provides an Analysis Polyphase Filter (APPF) for shifting a selected passband of an input signal to a passband signal, having a Q=M·B/A decimation factor, B and A being co-primes, the APPF comprising M·B Paths. Each path includes (i) M·B/A multiplication Sub-paths, and (ii) a Sub-path Fusion Circuit, which is configured to generate fused multiplication products responsively to a sum of the multiplication products generated by each of the multiplication sub-paths.

In some embodiments, the APPF further includes an input circuit, configured to receive and temporarily store input samples of the input signal at a subsampling ratio of Q:1. In an example embodiment, the input circuit includes a commutator, configured to sample the input signal according to an input commutation indication.

In some embodiments, the APPF further includes a circular output buffer, configured to output the fused multiplication products in a circular manner according to an output selection indication. In some embodiments, the APPF further includes an M-point Inverse-Fast-Fourier-Transform (IFFT) circuit, configured to convert the fused multiplication products into a polyphase-filtered output signal. In some embodiments, the APPF further includes a state engine, configured to generate an input commutation indication and an output selection indication.

There is additionally provided, in accordance with an embodiment that is described herein, a Synthesis Polyphase Filter (SPPF) for shifting a baseband signal to a passband of an output signal, having a Q=M·B/A interpolation factor, B and A being co-primes. The SPPF includes (i) M·B Paths, each path including M·B/A multiplication Sub-paths, and (ii) a Sub-path Expansion Circuit, which is configured to split multiplication products from the multiplication sub-paths.

In some embodiments, the SPPF further includes an M-point Inverse-Fast-Fourier-Transform (IFFT) circuit, configured to perform an Inverse-Fourier-Transform of the baseband signal, thereby producing an IFFT-transformed baseband signal. In an embodiment, the SPPF further includes a Circular Output Buffer, configured to receive, buffer and periodically output the IFFT-transformed baseband signal according to an output selection indication. In some embodiments, the SPPF further includes a state engine, to generate an output selection indication.

There is also provided, in accordance with an embodiment that is described herein, a Channelizer for shifting a passband in an input signal to a baseband signal. The channelizer includes an Analysis polyphase Filter (APPF), having a Q=M·B/A decimation/interpolation factor, B and A being co-primes. The APPF includes M·B Paths, each path including (i) M·B/A multiplication Sub-paths and (ii) a Sub-path Fusion Circuit, which is configured to generate fused multiplication products responsively to a sum of the multiplication products generated by each of the multiplication sub-paths.

There is further provided, in accordance with an embodiment that is described herein, an Up-Converter for shifting a baseband signal to a passband within an output signal. The Up-Converter includes a Synthesis Polyphase Filter (SPPF), having a Q=M·B/A decimation/interpolation factor, B and A being co-primes. The SPPF includes M·B Paths, each path including (i) M·B/A multiplication Sub-paths and (ii) a Sub-path Expansion Circuit, which is configured to split multiplication products from the multiplication sub-paths.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a Polyphase (PP) FIR filter with rational decimation factor, in accordance with an embodiment that is disclosed herein.

FIG. 1A is a block diagram that schematically illustrates an index-m PP Path of the PP FIR Filter of FIG. 1, in accordance with an embodiment that is disclosed herein;

FIG. 2 is a block diagram that schematically illustrates an Input Stage of a Polyphase FIR Filter, in accordance with an embodiment that is disclosed herein;

FIG. 3 is a block diagram that schematically illustrates a Rearranged Input Stage of a Polyphase FIR Filter, in accordance with an embodiment that is disclosed herein;

FIG. 4 is a block diagram that schematically illustrates an MB/A-path Gatling-Gun Input buffer, in accordance with an embodiment that is disclosed herein;

FIG. 5 is a block diagram that schematically illustrates a Group of MB/A FIR Filter Paths, in accordance with an embodiment that is disclosed herein;

FIG. 6A is a block diagram that schematically illustrates an MB-Path Input Data Buffer, in accordance with an embodiment that is disclosed herein;

FIG. 6B is a block diagram that schematically illustrates an MB/A-Path Input Data Buffer, in accordance with an embodiment that is disclosed herein;

FIG. 7A is a block diagram that schematically illustrates a complete MB-Path Analysis Polyphase Filter (APPF), in accordance with an embodiment that is disclosed herein;

FIG. 7B is a block diagram that schematically illustrates a complete MB/A-Path Analysis Polyphase Filter (APPF), in accordance with an embodiment that is disclosed herein;

FIG. 8 is a block diagram that schematically illustrates a Sub-Path Fusion Circuit, in accordance with an embodiment that is disclosed herein;

FIG. 9 is a block diagram that schematically illustrates a Synthesis Polyphase Filter, in accordance with an embodiment that is disclosed herein;

FIG. 10 is a block diagram that schematically illustrates a Sub-Path Expansion Circuit, in accordance with an embodiment that is disclosed herein;

FIG. 11A is a flowchart that schematically illustrates a method for rational decimation-rate polyphase FIR analysis, in accordance with an embodiment that is disclosed herein; and

FIG. 11B is a flowchart 1150 that schematically illustrates a method for rational decimation-rate polyphase FIR synthesis, in accordance with an embodiment that is disclosed herein.

### DETAILED DESCRIPTION OF EMBODIMENTS

### Overview

Polyphase filtering is a technique used to efficiently implement filter operations and sampling frequency changes. The M-path polyphase analysis filter bank (AFB) channelizer in its simplest realization—the maximally decimated filter bank—Given a wideband signal with sampling frequency fₛ, outputs M baseband time series from translated spectral bands centered at integer multiples of fₛ/M and with an equal bandwidth of fₛ/M. Similarly, the synthesis filter bank (SFB) up-converter, in its simplest realization—the maximally interpolated filter bank—given M baseband time series with a bandwidth fₛ/M, outputs a single wideband signal with sampling frequency, fₛ, and comprising the baseband signals now positioned at integer multiples of fₛ/M.

A polyphase-based implementation reduces the workload by a factor of M, rendering this algorithm attractive for applications with limited computational resources. Standard modifications to the channelizers include non-maximal decimation/interpolation with oversampling factor A/M, where A is a positive, non-zero integer. Specifically, a typical choice is A=2, which yields M/2-to-1 downsampling instead of M-to-1 at the AFB, or 1-to-M/2 up-sampling instead of 1-to-M at the SFB. When such a design is paired with a raised cosine prototype filter, neighboring channels construct coherently, which is referred to as Perfect Reconstruction filter banks. This enables a design suitable for channels with variable center frequencies and variable bandwidths. However, the non-maximal decimation/interpolation requires, when A=2, doubling the number of samples due to the doubled sampling rate, which can be a limiting factor (more than doubling samples may be required when A>2).

Embodiments that are disclosed hereinbelow adapt the M-path polyphase-based analysis and synthesis filter banks to rational oversampling factors of the form Afₛ/BM, where both A and B are natural numbers. In embodiments, perfect reconstruction for almost perfect reconstruction, according to the selected resolution and the accuracy of the raised-cosine filter) is achieved, with a relatively small amount of computing resources and power consumption.

In an embodiment, an AFB comprises an input buffer, to store input samples at locations according to an input commutation indication that is generated by State-Engine, followed by a multiplier bank. The Multiplier bank comprises Paths, each Path comprising Sub-Paths, wherein each Sub-Path multiplies an input sample by a corresponding coefficient. A Fusion circuit then sums products pertaining to the same Sub-Path; a Circular Output Buffer, timed by an output selection indication (generated by the State-Engine), periodically sends sums to an IFFT circuit, that outputs the band-pass signals.

In another embodiment, an SFB comprises an input IFFT circuit, followed by a circular buffer that stores IFFT samples. A Sub-Path Expansion circuit next splits the sample according to sub-paths, and an MB-Path filter multiplies the samples by corresponding coefficients. An MB-Path Output Buffer selectively sends the products to an A-part Gatling gun distributor, followed by adders, which outputs the pass-band signal.

Further embodiments disclose a Channelizer and a Channel-Up-Converter, that comprise, respectively, rational decimation and interpolation polyphase filters.

### System Description

A standard analysis filter pipeline comprises a Finite Impulse Response (FIR) Low-Pass Filter (LPF) followed by downsampling by a factor of Q.

Initially, an input signal x[n] that is sampled at a rate of fₛ, wherein n is a corresponding discrete time index, is fed to an FIR filter h[n] that comprises N filter taps. The output is:

$$y [ n ] = {\sum }_{t = 0}^{N - 1} h [ t ] x [ n - 1 ] \qquad ( 1 )$$

y[n] is then downsampled (decimated) at a factor of Q, to give

$$\tilde{y} [ l ] = y [ lQ ] \qquad ( 2 )$$

where 1 is the discrete time index at reduced sample rate fₛ/Q. Q is typically selected based on the characteristics of filter h[n]. From this point henceforth, we consider, without loss of generality, an LPF with a passband of 2π/M, for which Q≤M facilitates aliasing-free low-rate signals and Q=M gives the maximally decimated pipeline. The LPF Decimation pipeline is extended to a band-pass filter (BPF) by initially multiplying the input signal with a modulation series, in order to shift the input signal to baseband, prior to filtering. To avoid complex notation in the case of a BPF, the same notation of x[n] is updated also after multiplication by the modulator prior to the filter: i.e., x[n] is replaced by

$${e}^{- \frac{j 2 π k}{M}} ,$$

where k=0, 1, . . . , M−1 is the channels index, spanning a total of M channels.

The pipeline above may be implemented using an M-path polyphase filter. For the case of integer multiples of the maximally decimated pipeline, i.e., for Q=M/A, where A is an integer and for channels at 2πk/M for k=0, 1 . . . , M−1, the implementation follows a two-dimensional partition of the sum in Equation (1), and the application of the Noble Identity (NI) for each path. The two-dimensional partition maps the N filter taps in h[n] into M paths, each with L=N/M taps. It is assumed that M divides N without a remainder (when this is not the case, zero-padding can be applied). y[n] in this case is derived as:

$$y [ n ] = {\sum }_{m = 0}^{M - 1} {y}_{m} [ n ] \qquad ( 3 )$$

$$Where$$

$${y}_{m} [ n ] = {\sum }_{t = 0}^{N - 1} {h}_{m} [ t ] {x}_{m} [ n - t ] \qquad ( 4 )$$

and hm[n] is defined, via its Z transform as

$${H}_{m} ( Z ) = \hat{H} ( {Z}^{M} ) \qquad ( 5 )$$

where Ĥ(Z) is the Z transform of the maximally decimated polyphase partition given by

$$\hat{{h}_{m}} [ n ] = h [ nM + m ] \qquad ( 6 )$$

and with z^{M} in equation (5) signifying that the filter coefficients ĥₘ[n] are separated by M samples (or, equivalently, there are M−1 zeros between every two coefficients).

The signals in each path are defined as

$${x}_{m} [ n ] = x [ n - m ] . \qquad ( 7 )$$

The output of the filters in each path, {yₘ[n]} (m=0. . . M−1), are then downsampled, given as

$${\tilde{y}}_{m} [ l ] = {y}_{m} [ lQ ] . \qquad ( 8 )$$

The NI is applied to each of the paths separately and identically, exploiting the fact that the filter coefficients of hₘ[n] are separated by M samples (see equation (5)).

Initially, the xₘ[n] on each path are downsampled by a factor of Q, to give:

$${\tilde{x}}_{m} [ l ] = {x}_{m} [ lQ ] \qquad ( 9 )$$

with the updated filters now applied after the down-sampler, defined using the inverse Z transform of \tilde{H}(Z) as

$${\tilde{H}}_{m} ( Z ) = {\hat{H}}_{m} ( {Z}^{M / Q} ) \qquad ( 10 )$$

which is well-defined when Q=M/A is an integer. The output [symbol] ₘ[1] of each filter path is then given as

$$[ l ] = {\sum }_{t = 0}^{L - 1} [ t ] [ l - t ] \qquad ( 11 )$$

which is equivalent to \tilde{y}ₘ[l] from equation (8). This equivalence shows a reduced computation of L filter coefficients instead of a multiplication of N filter coefficients as in equation (4) followed by downsampling in equation (8).

$${[ l ] \}}_{m = 0}^{M - 1}$$

are now summed in a similar manner to equation (3), but now over the output signals at \tilde{ƒ}ₛ, i.e.,

$$\tilde{y} [ l ] = {\sum }_{m = 0}^{M - 1} [ l ] \qquad ( 12 )$$

Finally, the pipeline is extended to the case of bandpass by modulating the filters to passband and then modulating the filter output back to baseband.

An M-path polyphase filter design, with channels at 2πk/M, with k=0, . . . , M−1, comprises M paths, each path comprising a delay z^{-k} followed by a Ĥₘ(Z) filter and two exponential functions. The first exponential function is a time series

$${{\{ exp \{ ( - j Q \frac{2 π kl}{M} \} ) \}}_{k = 0}^{M - 1} = \{ exp \{ ( - j \frac{2 π kl}{A} \} ) \}}_{k = 0}^{M - 1} \qquad ( 13 )$$

That is identical for all paths modulating the filter output to baseband (Note that for A=1, this exponent equal unity for all 1, and is, thus, omitted).

The second exponential function is a constant in each path, given by exp (−j*(2πkm/M)) and charged with modulating the filters to passband.

Note that modulating the filters typically requires multiplying the filter t with a modulation series. However, as the modulation series are periodic over M for all k=0, . . . , M−1, the modulation series in each path is a constant; furthermore, as it is constant, it is typically positioned at the end of the pipeline and implemented using an inverse fast Fourier transform (IFFT) for all k=0, . . . , M−1 simultaneously, to reduce computation.

For more details regarding an M-path polyphase implementation including a frequency domain interpretation of the signals in each path, the reader is referred to Chapter 6 of “Multirate Signal Processing for Communication Systems”, by F. J. Harris et al, cited above.

The polyphase presented above facilitates the design of perfect-reconstruction (PR) (or nearly PR) filter banks when setting A≥2, which facilitates application-specific requirements of variable center frequency and variable bandwidths.

Specifically, A=2 or, alternatively, Q−M/2 is a common solution for facilitating PR filter banks.

Using Equation (10), Ĥₘ(Z) in this case are given as Ĥₘ(Z)=Hₘ^{max}(Z²), which can be interpreted as a separation of the filter coefficients (in each path) by two samples. This requires storing double the number of registers (for each path) compared to the case of A=1.

Furthermore, in this case, the first exponential function reduces to exp (−jπkl), which means phase shifts of π for odd values of k.

These shifts are typically treated by applying circular shifts to time-domain signals to avoid multiplication with complex exponential functions.

### Rational Decimation/Interpolation Factors

Embodiments to be disclosed herein comprise polyphase filters with rational multiples of the maximally decimated pipeline, i.e., for Q=MB/A, where B is also an integer value, and wherein B and A are co-primes. We decompose each of the M paths to B polyphase sub-paths prior to the application of NI, while exploiting the knowledge that the filter taps in each path prior to the NI application are separated by M samples (see Equation 5).

This is applied to each path separately and identically. Without loss of generality, the solution is now derived for path m.

The filter in path m is partitioned into B sub-paths prior to the application of the NI:

$${y}_{m} [ n ] = {\sum }_{b = 0}^{B - 1} {y}_{( m , b )} [ n ] \qquad ( 14 )$$

$$where$$

$${y}_{( m , b )} [ n ] = {\sum }_{t = 0}^{N - 1} {h}_{( m , b )} [ t ] {x}_{( m , b )} [ n - t ] \qquad ( 15 )$$

the signals in each of the B sub-paths, {x_{(m,b)}[n]}_{b=0}^{B-1}, are defined similarly to xₘ[n] from Equation (7), but with shift of M (see Equation 5), as

$${x}_{( m , b )} [ n ] = {x}_{m} [ n - bM ] , \qquad ( 16 )$$

and h_{(m,b)}[n] are defined as in the case of hₘ[n] from Equation (4), via its Z-transform, H_{(m,b)}(z) similarly to Equation (5) as

$${H}_{( m , b )} ( Z ) = {\hat{H}}_{( m , b )} ( {Z}^{B} ) , \qquad ( 17 )$$

with Ĥ_{(m,b)} being the z transform of the maximally-decimated polyphase path, defined similarly to Equation (6)

$${\hat{H}}_{( m , b )} [ n ] = [ nB + b ] . \qquad ( 18 )$$

The NI for Q=MB/A can now be applied in order to reduce the computations, as compared to the direct implementation.

Initially, the downsampled signals and filters are defined for each of the sub-paths x_{(m,b)}[n] on each path are downsampled by a factor of Q, similarly to Equation (9), as

$${\tilde{x}}_{( m , b )} [ l ] = {x}_{( m , b )} [ l Q ] \qquad ( 19 )$$

and with the updated filters derived similarly to equation (10), but with respect to Ĥ₍ₘ₎(Z^{M}) (see equation (5)). Following equation (17), this gives

$${\hat{H}}_{( m , b )} ( {Z}^{M} ) = {\hat{H}}_{( m , b )} ( {Z}^{M B / Q} ) = {\hat{H}}_{( m , b )} ( {Z}^{A} ) \qquad ( 20 )$$

which is well-defined for integer values of A, and indicates that the filter taps in each path are separated by A samples (or A−1 zeros).

The output of the filter in each sub-path after the application of the NI, ŷ_{(m,b)}[l], is given similarly to equation (11) as

$${\tilde{y}}_{( m . b )} [ l ] = {\sum }_{t = 0}^{L - 1} {\tilde{h}}_{( m , b )} [ t ] {\tilde{x}}_{( m , b )} [ l - t ] , \qquad ( 21 )$$

where L, is the number of non-zero taps of the filter in each sub-path, which, in this case, equal N/(MB).

The last equation is equivalent to first calculating y_{(m,b)}[n] from Equation (15) and then downsampling by a factor of Q, i.e., \tilde{y}_{(m,b)}[l]=y_{(m,b)}[lB], similarly to equation (8).

{\tilde{y}_{(m,b)}[l]}_{b=0}^{B-1} are now summed in a similar manner to equation (14), i.e.,

$${\tilde{y}}_{m} [ l ] = {\sum }_{b = 0}^{B - 1} {\tilde{y}}_{( m , b )} [ l ] . \qquad ( 22 )$$

The extension to the case of bandpass signals is similar to the extension presented in the case of downsampling factors of the form Q=M/A shown above, with the first exponential now adjusted to the new downsampling factor, i.e., as in equation (13), but with Q=MB/A.

### Architecture of a Rational Decimation/Interpolation Ratio PP Filter with Gatling-Gun Input Buffer

Based on the analysis above and adding a novel circuit for fusing sub-paths (in the case of an analysis pipeline) or for expanding the sub-paths (in the case of a synthesis pipeline), we will now disclose an M-path, MB-sub-path PP filter.

We define a new index, \tilde{m} as:

$$\tilde{m} = m + bM , \tilde{m} = 0 , … , MB - 1. \qquad ( 23 )$$

We also note that given \tilde{m}, indices m and b, which were defined above for an M-path-based design, can be extracted using:

$$m = mod ( \tilde{m} , M ) \qquad ( 24 )$$

$$and$$

$$b = floor ( \tilde{m} , M ) \qquad ( 25 )$$

The paths and sub-paths of an M-path-based design presented above are now arranged according to index \tilde{m} and use suitable MB-sub-paths.

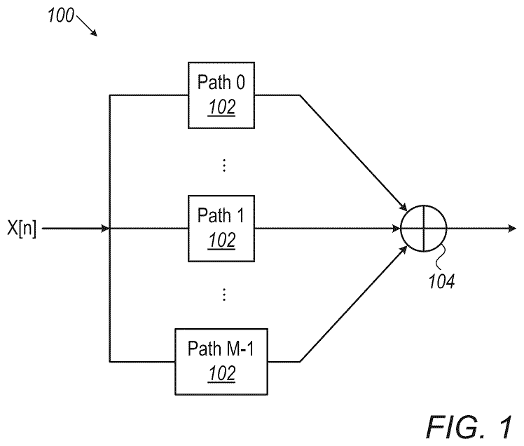

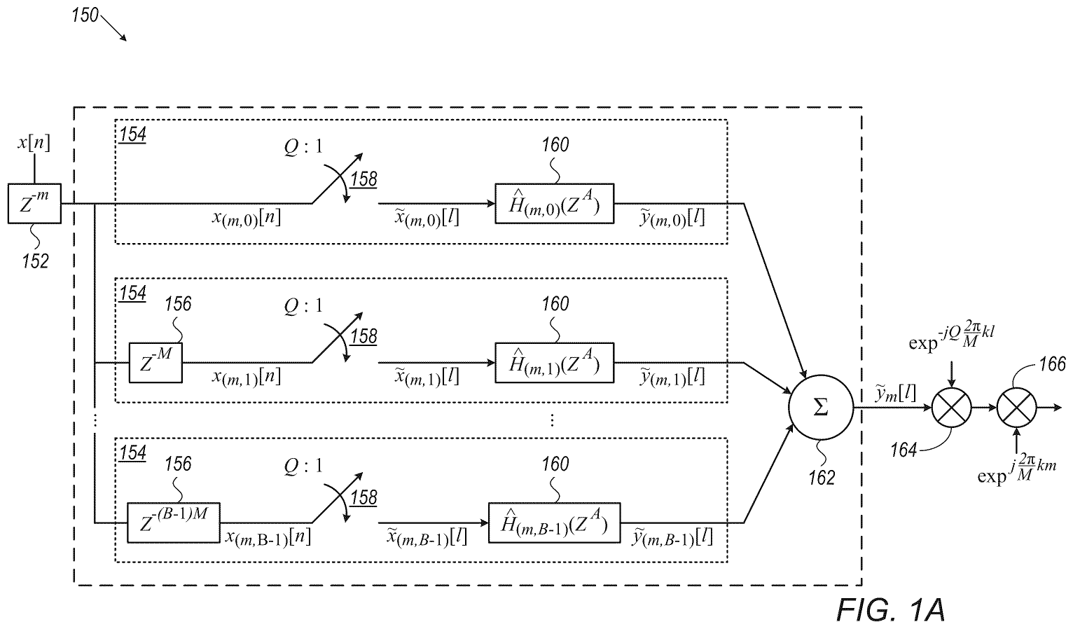

FIG. 1 is a block diagram that schematically illustrates an Analysis Polyphase (PP) Filter (APP) 100 with rational decimation factor, in accordance with an embodiment that is disclosed herein.

APP Filter 100 comprises M−1 PP Paths 102 that are driven by the signal x[n], and an Adder 104, configured to generate the PP filter outputs y[n] according to the sum of the M paths.

FIG. 1A is a block diagram that schematically illustrates an index-m PP Path 150 of the APP Filter 100, in accordance with an embodiment that is disclosed herein. The Path comprises a Path-Delay circuit 152, which is configured to delay the input signal x[n] by m clock cycles. The delayed input signal then splits to B Sub-Paths 154. Each Sub-Path 154 comprises a Sub-Path-Delay 156, a Down-sampler 158, a FIR Filter 160, and a Summation circuit 162.

Sub-Path-Delay 156 delays the signal by m*M, where m is 0 for the first sub-path (and, hence, the Sub-Path-Delay for the first Sub-Path, with m=0, is not shown), 1 for the next Sub-Path and so on. Sub-Sampler 158 sub-samples the output of the Sub-Path-Delay circuits by a ratio of Q:1. The sub-sampled outputs are denoted \tilde{x}_{(m, i)}[l] and the outputs of filter 160 are denoted \tilde{y}_{(m,i)}[l], where m is the path index, ranging from 0 to M−1 and i is the sub-path index, spanning from 0 to B−1.

PP Path 150 further comprises a First-Exponent circuit 164, configured to multiply \tilde{y}_{(m,i)}[l] by exp (−jQ*2π/M*kl), and a Second-exponent circuit 166, configured to multiply the output of First Exponent Circuit 164 by exp (j*2π/M*km).

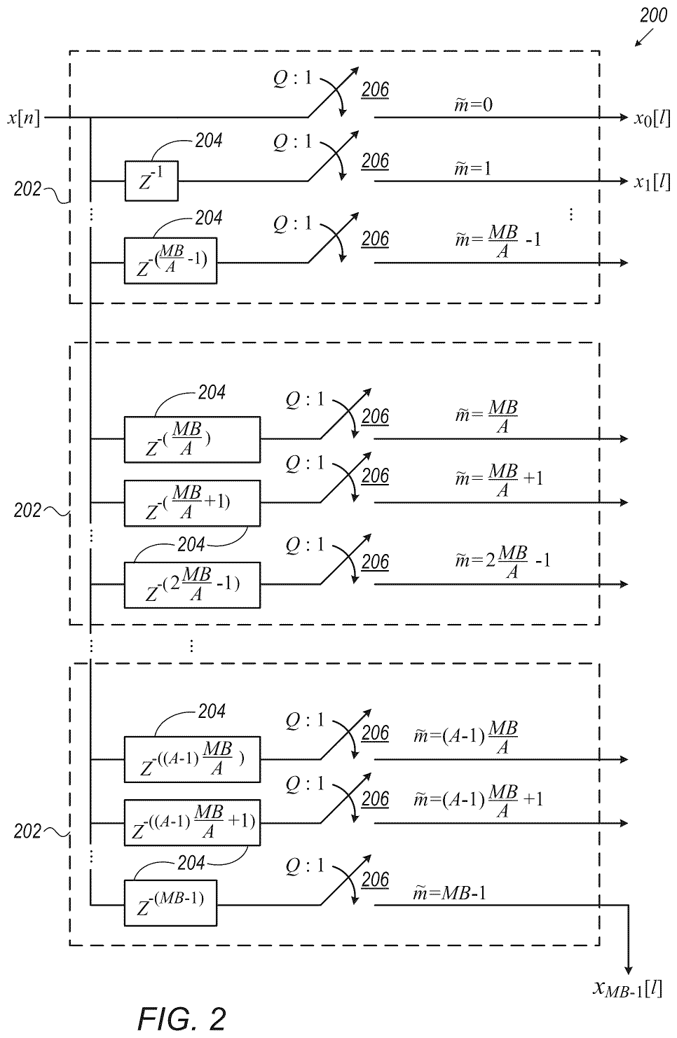

FIG. 2 is a block diagram that schematically illustrates an Input Stage 200 of Analysis Polyphase Filter (APP), in accordance with an embodiment that is disclosed herein. Input Stage 200 is identical to Analysis Polyphase Filter (APP) 100 (FIG. 1), but without the Filters 160, the Summation Circuits 162, the First Exponent Circuits 164 and the Second Exponent Circuits 166. Delay Circuits 204 delay the input signals according to the Path and Sub-Path, and Sub-Samplers 206 sub-sample the delayed signals by a ratio of Q:1.

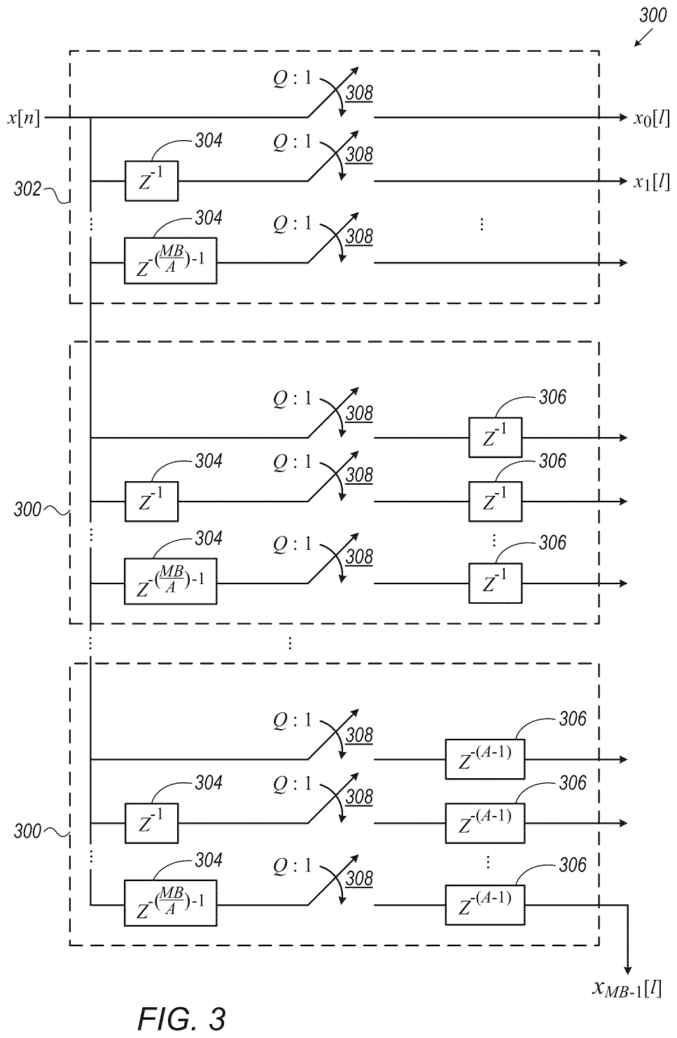

FIG. 3 is a block diagram that schematically illustrates a Rearranged Input Stage 300 of a Polyphase FIR Filter, in accordance with an embodiment that is disclosed herein. (Note that both FIG. 2 and FIG. 3 follow the same rearranged input stage; the main difference between them is the application of the Noble Identity on a common group delay over A blocks) The Rearranged Input Stage comprises Paths 300. The delay circuits 204 (FIG. 2) are now divided to two—a First Delay 304, and, where applicable, a Second Delay 306. The two delays in each path are separated by Sub-Samplers 308.

As can be observed in FIG. 3, only MB/A paths at high-sampling rate are required, while the rest of the paths in the MB-path design can be defined as delayed versions of the first MB/A. This is useful for the construction of an MB-path input data buffer that uses an MB/A-path Gatling gun input buffer.

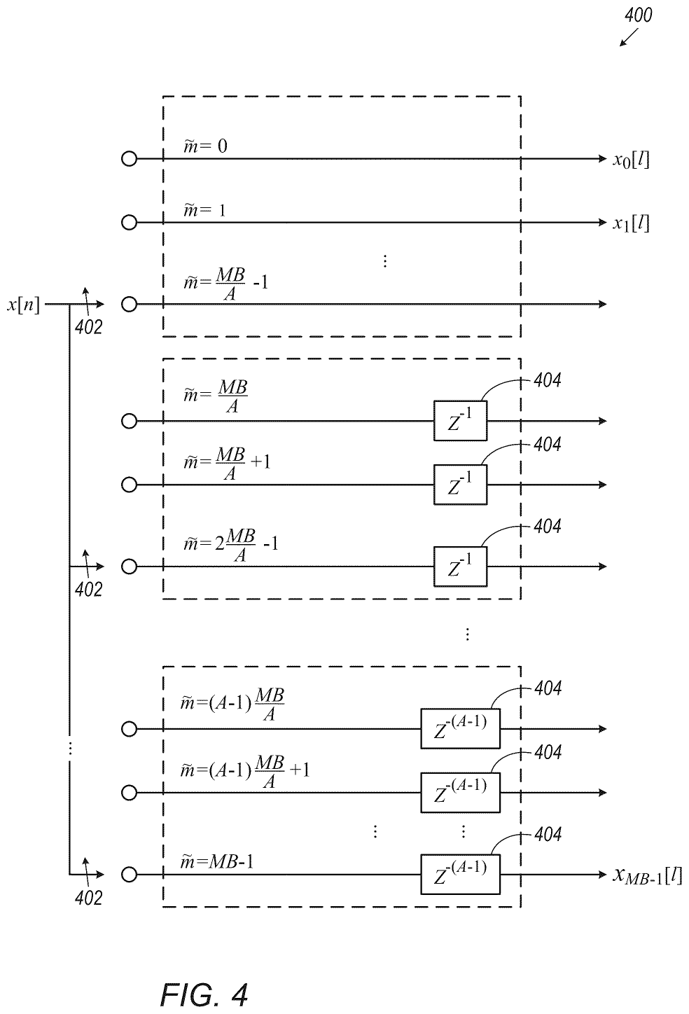

FIG. 4 is a block diagram that schematically illustrates an MB/A-path Gatling-Gun Input buffer 400, in accordance with an embodiment that is disclosed herein.

Gatling-Gun Input buffer 400 is like Rearranged Input Stage 300, but the input delays 304 and the Down-Samplers 308 are now replaced with MB/A A-factor commutators 402, that send selected inputs according to a commutation selection indication, to Delay Lines 404. We note that a single input data register of dimensions A×N/B is sufficient for computation of all paths using shifts.

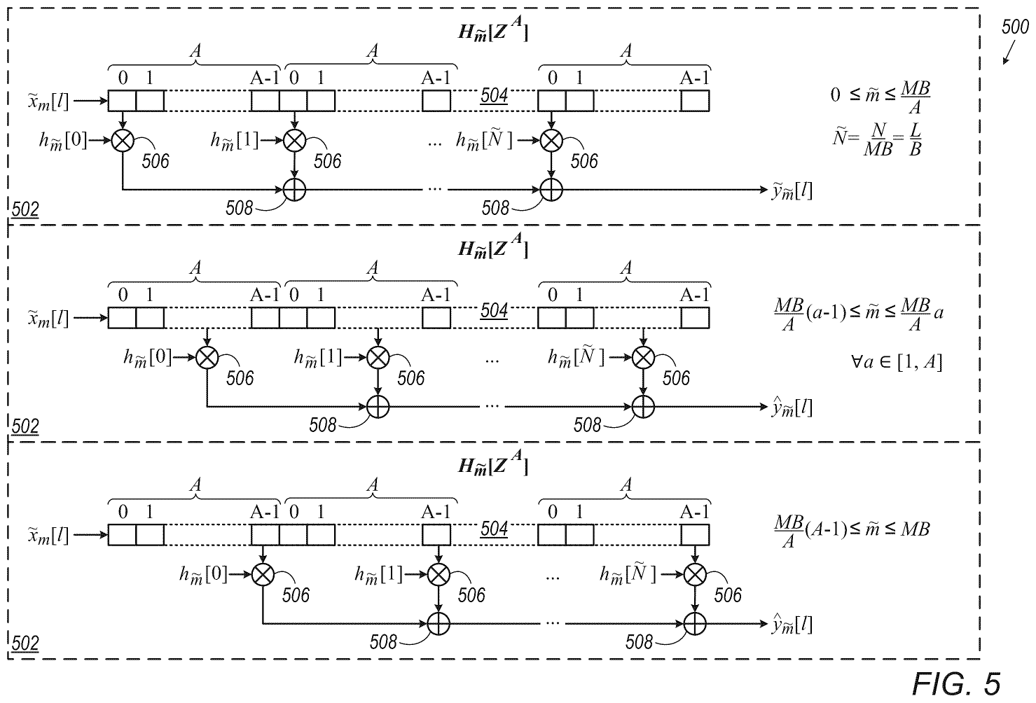

FIG. 5 is a block diagram that schematically illustrates a Group 500 of MB/A FIR Filter Paths 502, in accordance with an embodiment that is disclosed herein.

Each FIR Filter Paths 502 comprises a Shift Register 504 that stores the input samples \tilde{x}ₘ[l], multipliers 506 that multiply taps of the Shift Register 504 by set of respective coefficients and adders 508 that add the multipliers outputs, to generate \tilde{y}ₘ[l]. Note that in various embodiments, Shift Register 504 may be common to all FIR Filter Paths 502; in other embodiments, two or more of FIR Filter Paths 502 may share a single copy of Shift Register 504.

The top MB/A filters use input-signal indices with mod(n,A)=0, and, in general, α group x of MB/A paths uses indices mod(n,A)=α−1.

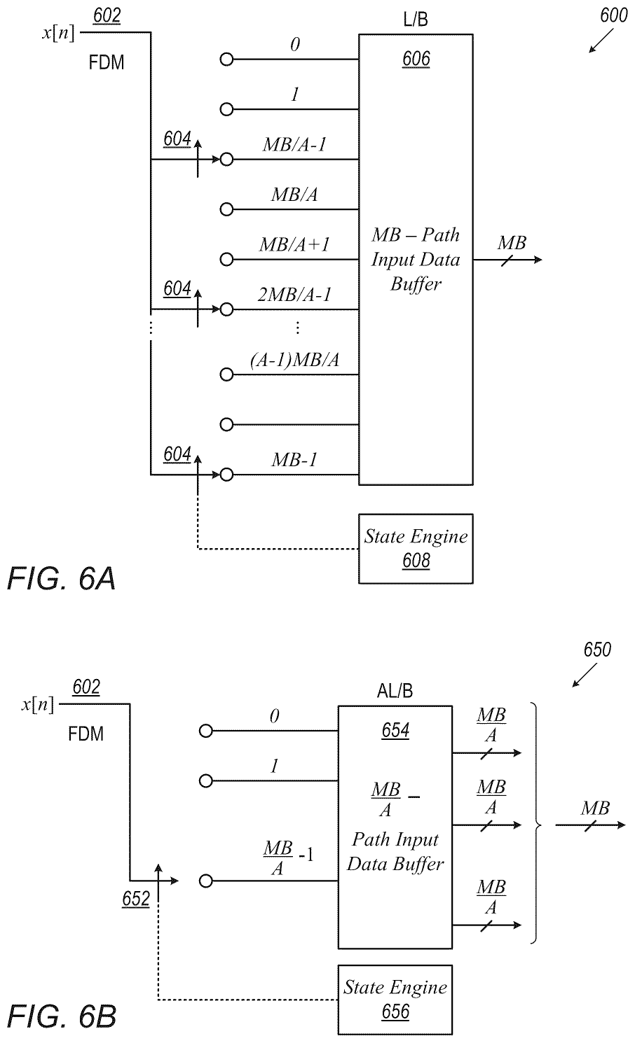

FIG. 6A is a block diagram that schematically illustrates an MB/A-Path Input Data Buffer 600, in accordance with an embodiment that is disclosed herein.

FIG. 6B is a block diagram that schematically illustrates an MB-Path Input Data Buffer 650, in accordance with an embodiment that is disclosed herein. In both MB/A-Path Input Data Buffer 600 and MB-Path Input Data Buffer 650, an Input Signal x[n] 602 is stored in an input data buffer. In the case of Input Data Buffer 600, Commutators 604 send the input data samples to storage cells in an MB-Path Input Data Buffer 606, and, in the case of Input Data Buffer 650, a single commutator 652 sends the data samples for storage in an MB/A-Path Input Data Buffer 654. A State-Engine 608 and a State Engine 656 change state with a periodicity of MB clock cycles, and generate input commutation indications, which governs commutators 604 and 652, respectively.

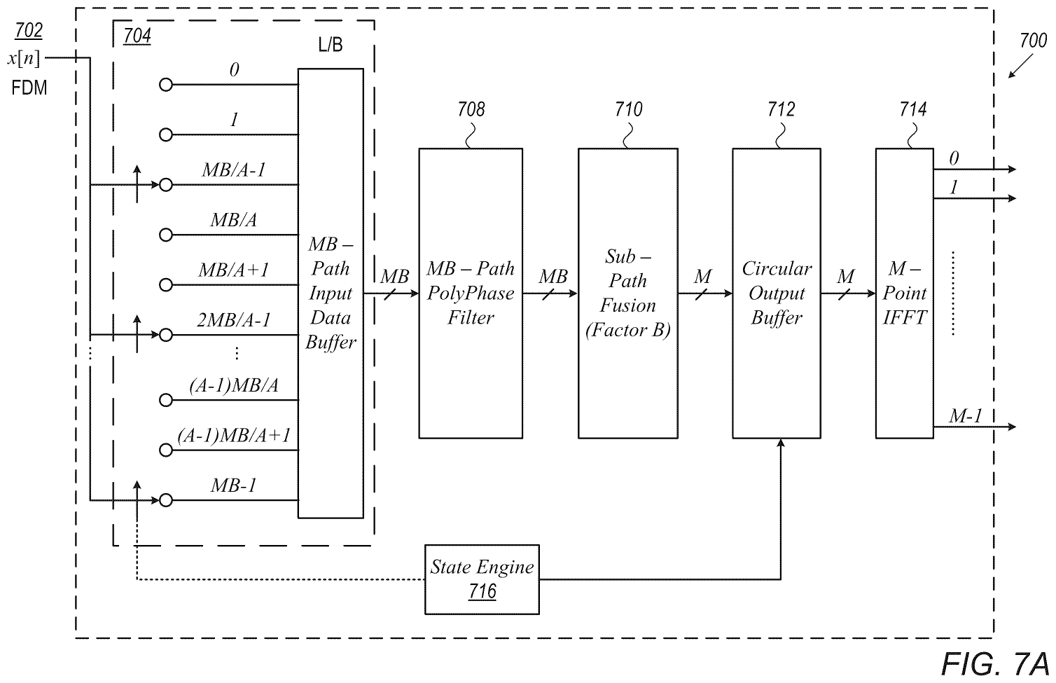

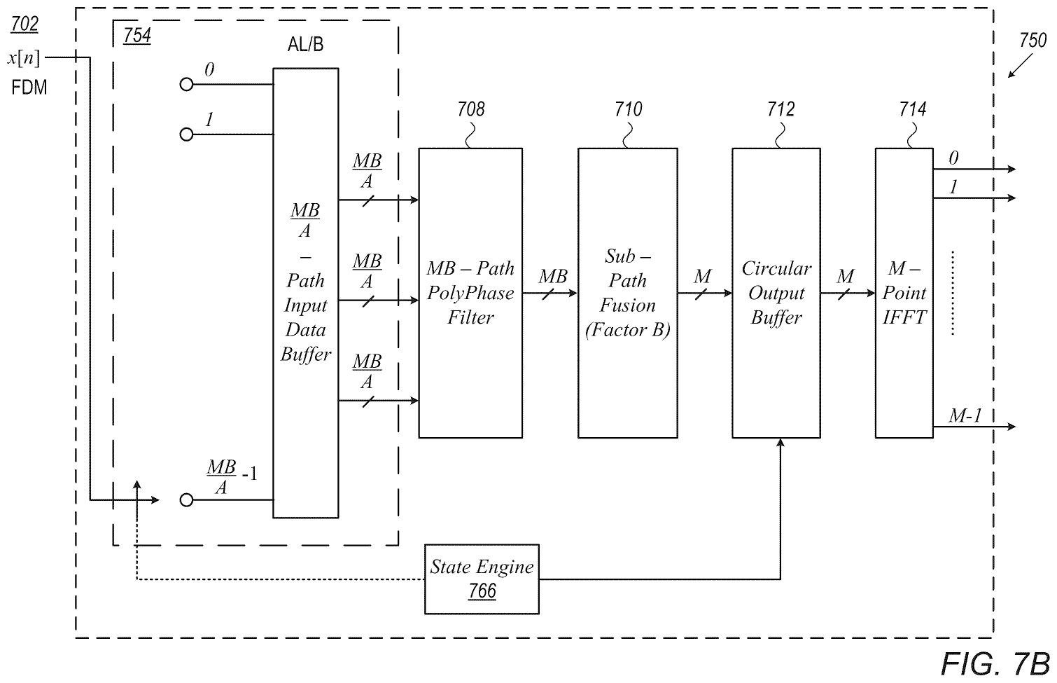

FIG. 7A is a block diagram that schematically illustrates a complete MB-Path Analysis Polyphase Filter (APPF) 700, in accordance with an embodiment that is disclosed herein. The MB-Path APPF 700 comprises an Input Data Buffer 704 (which is identical to MB/A-Path Input Data Buffer 600, FIG. 6A), an MB-path polyphase filter 708 with a rational decimation factor Q=MB/A, an MB-Path Polyphase Filter 708 (comprising the Group of MB/A FIR Filter Paths 500 (FIG. 5)), A Sub-Path Fusion Circuit 710, configured to add the partial sub-path products (producing fused multiplication products), a Circular Output Buffer 712, configured to periodically output the filtered samples according to an output selection indication, and an M-Point Inverse-Fast-Fourier-Transform (IFFT) circuit 714, configured to execute the exponent functions 164, 166 (FIG. 1B) and generate all the time-domain signals for all M channels. To control both the Input Buffer 704 and the Circular Buffer 712, APPF 700 further comprises a State-Engine 716 that changes state with a periodicity of MB clock cycles and sends suitable control signals to the Input Buffer and to the Circular Output Buffer.

In a similar manner, FIG. 7B is a block diagram that schematically illustrates a complete MB/A-Path Analysis Polyphase Filter (APPF) 750, in accordance with an embodiment that is disclosed herein. MB/A-Path APPF 750 is like M-Path APPF 700 and comprises the same sub-units, except that the Polyphase Filter 750 comprises an Input Data Buffer 754, which is identical to MB-Path Input Data Buffer 650, FIG. 6B), and except that MB/A-Path APPF 750 comprises a State Engine 766, to control the Input Data Buffer 754.

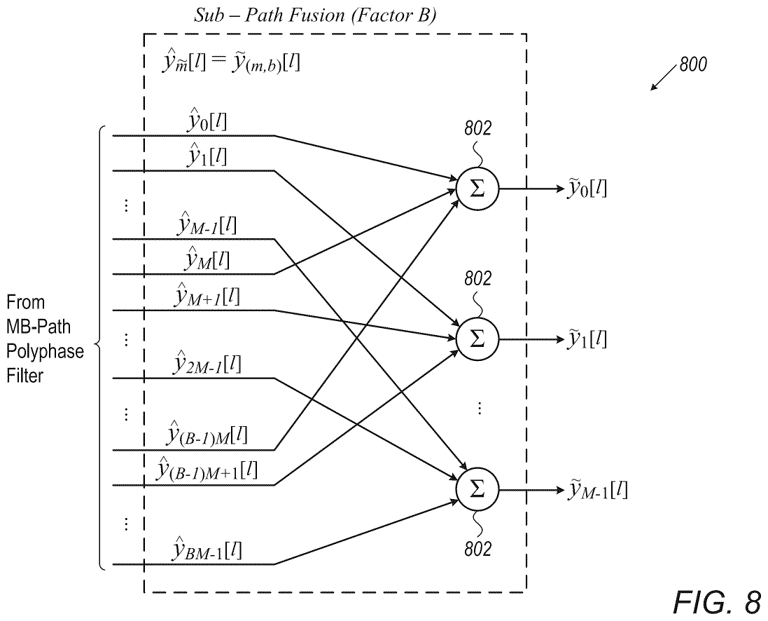

FIG. 8 is a block diagram that schematically illustrates a Sub-Path Fusion Circuit 800, in accordance with an embodiment at is disclosed herein. The Sub-Path Fusion Circuit 800 executes the summation of Equation 22, using M Adders 802, to sum the MB products output from the MB-Path Polyphase Filter into fused multiplication products, which are then input to the circular buffer, according to the output indices ŷᵢ[l]. (We define for ŷ anew index \tilde{m}, where m scans all m*B m,b combinations.)

### Synthesis

While the Analysis filter decomposes an input signal to sub-bands, the Synthesis filter reconstructs the signal from its M narrowband signals. Rational ratio synthesis polyphase filter can be built from the Analysis design using the Duality Principle.

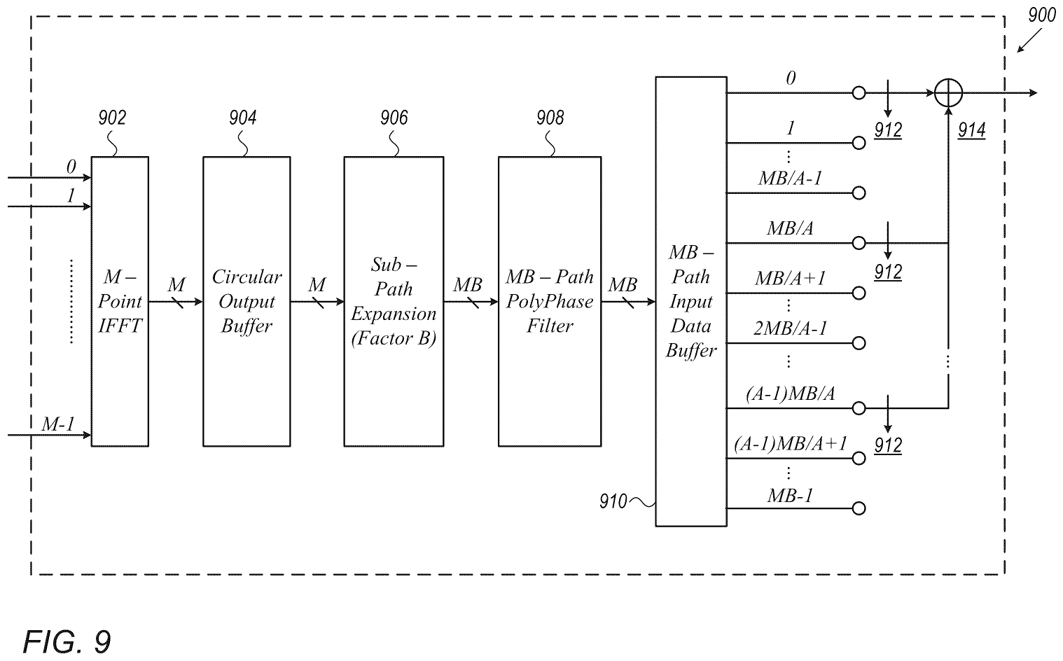

FIG. 9 is a block diagram that schematically illustrates a Synthesis Polyphase Filter 900, in accordance with an embodiment that is disclosed herein. The Polyphase Filter 900 comprises an IFFT circuit 902 that receives a baseband signal and generates an IFTT-transformed baseband signal, a Circular Output Buffer 904 that periodically forwards samples of the input signal according to an output selection indication (sent by the State Engine), a Sub-Path Expansion Circuit 906, which is the dual counterpart of Sub-Path Fusion Circuit 710 (FIG. 7A), an MB-Path Polyphase Filter 908, (which is like MB-Path Polyphase Filter 708, FIG. 7A), an MB-Path Input Data Buffer 910, Rotating-Selectors 912, which selectively select outputs of the Input Data Buffer 910, according to a repetitive order, and, an Adder 914, which sums the outputs of the Rotating Selectors.

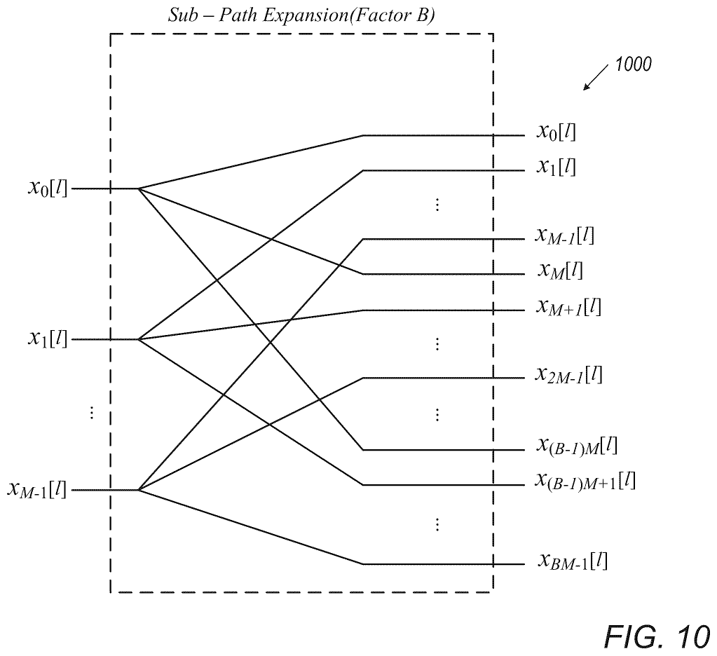

FIG. 10 is a block diagram that schematically illustrates a Sub-Path Expansion Circuit 1000, in accordance with an embodiment that is disclosed herein. The Sub-Path Expansion Circuit splits the Xᵢ[l] (l is the path index, and i is the signal index, from 0 to B−1), to suitable MB-Path Polyphase Filter inputs, inversely to the operation of Sub-Path Fusion Circuit 800 (FIG. 8).

Thus, according to the embodiments disclosed herein above, M-path Polyphase analysis and synthesis filter banks with rational decimation filters can be built; the filters include traditional pipeline stages along with novel fusing/expansion circuits. The filters facilitate a reduced computation load due to the use of an M-path IFFT. The total number of computations is BM for fusing sub-paths M times, plus M*log (M) computations in the IFFT.

### Channelizer and Up-Converter

The rational down/up sampling polyphase filter banks described above can be used, for example, in a Channelizer that separates a broadband input signal into multiple narrow passbands, or in an up-converter, that shifts a baseband channel to a passband within a higher frequency signal. In an embodiment, a Channelizer comprises some or all of the sub-modules of Analysis Polyphase Filter 700 or 750 (FIGS. 7A, 7B). In another embodiment, an Up-converter comprises some or all of the sub-modules of a Synthesis Polyphase filter 900 (FIG. 9).

### Methods

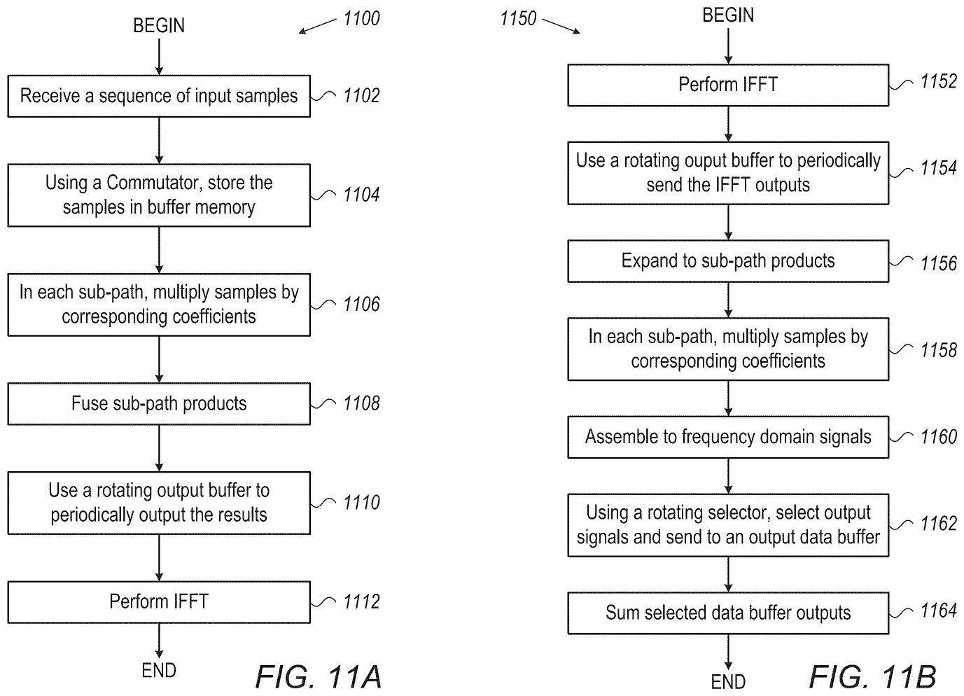

FIG. 11A is a flowchart 1100 that schematically illustrates a method for rational decimation-rate polyphase FIR analysis, in accordance with an embodiment that is disclosed herein. The flowchart is executed by Analysis Polyphase Filter (APPF) 700 (FIG. 7A). As described above, an Analysis filter, in the present contents, moves a selected band withing a wideband signal to the baseband.

The flowchart starts at a Receive Input Sequence operation 1102, wherein the APPF receives a sequence of input samples Xᵢ, for example, from an Analog to Digital Converter (ADC). Next, at a Store-Input-In-Buffer operation 1104, the APPF stores the input samples in an input buffer, using a Commutator that is governed by an input commutation indication, sent by the State Engine. The Commutator distributes the samples to buffer cells that will then be accessed for filtering, as described above, with reference to FIGS. 6A and 6B.

Now, at a Multiply-by-Coefficient operation 1106, the APPF multiplies the samples from the input buffer by corresponding coefficients, separately in each of the A sub-paths of the MB/A paths.

Next, at a Fuse-Sub-Path operation 1108, the APPF sums up the products that correspond to the same index i of outputs \tilde{y}ᵢ[l], using Fusion Circuit 800 (FIG. 8).

Now, at a Rotating-Output operation 1110, The APPF, sends the fused results, from the Circular Output Buffer 712 (FIG. 7) that is governed by the output selection indication (generated by State-Engine 766), to the IFFT circuit 714.

Lastly, at an IFFT operation 1112, the IFFT circuit 714 (FIG. 7A) executes an M-point IFFT conversion, to transform the fused results into the APPF outputs 0 through M−1.

FIG. 11B is a flowchart 1150 that schematically illustrates a method for rational decimation-rate polyphase FIR synthesis, in accordance with an embodiment that is disclosed herein. The flowchart is executed by Synthesis Polyphase Filter (SPPF) 900 (FIG. 9), and by sub-unit thereof (all illustrated in FIG. 9). As described above, a Synthesis filter, in the present contents, moves a baseband signal to a band withing a wideband signal.

The flowchart starts at an IFFT operation 1152, wherein IFFT circuit 902 converts the M inputs to a time-domain series. Next, at a Periodic-Sample-Output operation 1154, the Circular Output Buffer 904 outputs IFFT-converted samples, according to a rotating scheme.

Now, at an Expand operation 1156, the Sub-Path-Expansion circuit 906 expands the samples by a ratio of 1:B.

Next, at a Multiply-by-Coefficients, the samples are multiplied, in separately in each of the A sub-paths of the MB/A paths, and, at a subsequent Assemble-to-Frequencies operation 1160, groups of products pertaining to the same frequency bands are assembled.

Now, at a Rotating-Select operation 1162, Rotating-Selectors 912 select outputs on a rotating order (according to a State-Engine that counts clocks). Lastly, at a Sum Outputs operation 1164, Adder 924 adds the selected outputs, to form Y[n].

Although the apparatuses and methods disclosed hereinabove mainly refer to polyphase FIR filter analysis and synthesis, the present invention is not limited to polyphase FIR filters; any other suitable filters may be used in alternative embodiments.

The configurations of Analysis Filter-Banks 700 and 750, including Input Data Buffers 704 and 754, MB-Path Polyphase Filter 708, Sub-Path Fusion circuit 710 and Circular Output Buffer 712; the configuration of Synthesis Filter Bank 900, including Circular Output Buffer 904, Sub-Path Expansion circuit 906, MB-Path Polyphase Filter 908, MB-Path Input Data Buffer 910, Selector 912 and Adder 914, including all subcircuits thereof, the methods of flowcharts 1100, 1150, illustrated in FIGS. 1 through 11 and described hereinabove, are example configurations and methods that are shown purely for the sake of conceptual clarity. Any other suitable configurations and methods can be used in alternative embodiments.

The different elements of Analysis Polyphase Filter 700, 750 and Synthesis Polyphase Filter 900 may be implemented in an integrated circuit, such as an application specific integrated circuit (ASIC) or a field-programmable gate-array (FPGA).

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An Analysis Polyphase Filter (APPF) for shifting a selected passband of an input signal to a passband signal, having a Q=M·B/A decimation factor, B and A being co-primes, the APPF comprising M·B Paths, each path comprising (i) M·B/A multiplication Sub-paths, and (ii) a Sub-path Fusion Circuit, which is configured to generate fused multiplication products responsively to a sum of the multiplication products generated by each of the multiplication sub-paths.

2. The APPF according to claim 1, further comprising an input circuit, configured to receive and temporarily store input samples of the input signal at a subsampling ratio of Q:1.

3. The APPF according to claim 2, wherein the input circuit comprises a commutator, configured to sample the input signal according to an input commutation indication.

4. The APPF according to claim 1, further comprising a circular output buffer, configured to output the fused multiplication products in a circular manner according to an output selection indication.

5. The APPF according to claim 1, further comprising an M-point Inverse-Fast-Fourier-Transform (IFFT) circuit, configured to convert the fused multiplication products into a polyphase-filtered output signal.

6. The APPF according to claim 1, further comprising a state engine, configured to generate an input commutation indication and an output selection indication.

7. A Synthesis Polyphase Filter (SPPF) for shifting a baseband signal to a passband of an output signal, having a Q=M·B/A interpolation factor, B and A being co-primes, the SPPF comprising (i) M·B Paths, each path comprising M·B/A multiplication Sub-paths, and (ii) a Sub-path Expansion Circuit, which is configured to split multiplication products from the multiplication sub-paths.

8. The SPPF according to claim 7, further comprising an M-point Inverse-Fast-Fourier-Transform (IFFT) circuit, configured to perform an Inverse-Fourier-Transform of the baseband signal, thereby producing an IFFT-transformed baseband signal.

9. The SPPF according to claim 8, further comprising a Circular Output Buffer, configured to receive, buffer and periodically output the IFFT-transformed baseband signal according to an output selection indication.

10. The SPPF according to claim 7, further comprising a state engine, to generate an output selection indication.

11. A Channelizer for shifting a passband in an input signal to a baseband signal, the channelizer comprising an Analysis polyphase Filter (APPF), having a Q=M·B/A decimation/interpolation factor, B and A being co-primes, the APPF comprising M·B Paths, each path comprising (i) M·B/A multiplication Sub-paths and (ii) a Sub-path Fusion Circuit, which is configured to generate fused multiplication products responsively to a sum of the multiplication products generated by each of the multiplication sub-paths.

12. An Up-Converter for shifting a baseband signal to a passband within an output signal, the Up-Converter comprising a Synthesis Polyphase Filter (SPPF), having a Q=M·B/A decimation/interpolation factor, B and A being co-primes, the SPPF comprising M·B Paths, each path comprising (i) M·B/A multiplication Sub-paths and (ii) a Sub-path Expansion Circuit, which is configured to split multiplication products from the multiplication sub-paths.
